(19) United States
(12) Patent Application Publication
(10) Pub. No.: US 2024/0332050 A1
(43) Pub. Date: Oct. 3, 2024

(54) CARRIER ASSEMBLY FOR CARRYING SEMICONDUCTOR PACKAGE STRIPS WITH IMPROVED WARPAGE CONTROL

(71) Applicant: JCET STATS ChipPAC Korea Limited, Incheon (KR)

(72) Inventors: SeungHyun LEE, Incheon (KR); DaYoung KWON, Incheon (KR); YuJin HWANG, Busan (KR)

(21) Appl. No.: 18/613,170

(22) Filed: Mar. 22, 2024

(30) Foreign Application Priority Data
Mar. 28, 2023 (CN) 202310313203.5

(51) Int. Cl. H01L 21/673

(52) U.S. Cl. CPC H01L 21/67373

(57) ABSTRACT

A carrier assembly comprises a carrier main body comprising a housing, the housing comprising side walls having supporting slots for carrying the semiconductor package strips inside the housing, respectively, and the housing defining a front opening and a rear opening between the side walls to allow for placement and displacement of the semiconductor package strips, and a pair of clamping devices for applying clamping forces to the semiconductor package strips against the supporting slots, respectively, and each of the pair of clamping device comprising a locking plate, strip contacting extensions extending from the locking plate and insertable through one of the front opening and the rear opening of the housing, and a locking member for moving the strip contacting extensions between a locked position and an unlocked position, wherein in the locked position the substrate package strips are pressed against the supporting slots by the respective strip contacting extensions.

### TECHNICAL FIELD

The present invention relates in general to semiconductor manufacturing and, more particularly, to a carrier assembly for carrying semiconductor package strips with improved warpage control, especially during transport and manufacturing processes.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays.

A conventional semiconductor wafer typically contains a plurality of semiconductor die that can be separated by respective saw streets. Active and passive circuits are formed in a surface of each semiconductor die. An interconnect structure can be formed over the surface of the semiconductor die. The semiconductor wafer is singulated into individual semiconductor die for use in a variety of electronic products. The individual semiconductor die is typically sealed within a package, i.e., packaged, for electrical interconnect, structural support, and environmental protection and forms an semiconductor package. The semiconductor die is then physically and electrically connected to a carrier or substrate, forming a semiconductor package strip, referred to as a package strip or a strip in the following. An encapsulant may then be formed over the semiconductor package strip. Encapsulant may be any type, for example, a thermal set overmold or a glob.

The packaging process sometimes involves application of heat, such as during curing, baking, and molding. For example, when encapsulant is applied by molding, a pre-baking before molding process (PBM) is performed before encapsulation of the strip, for the purpose of eliminating voids and avoiding delamination risks by removing moisture in the strip. Post curing can also be performed after molding. For PBM, the strips may be placed inside a carrier, commonly referred to as a magazine. FIG. 1A and FIG. 1B show package strips S each having one or more semiconductor dice C attached to a package strip plate P, which are all placed inside a conventional magazine 102. The magazine 102 includes a housing 103 having, on its internal surface 104, supporting slots 106, for example horizontally extending slots or grooves, for carrying the strips S inside the housing 103. As can be seen, in the conventional magazine illustrated in FIGS. 1A and 1B, the strips S may dislocate from their resting locations if the magazine 102 is dropped or subject to other unintended movement, thus are subject to damage during transport of the magazine 102 or in other situations. Further, as illustrated in FIG. 1B, the application of heat to the strips S can cause the strip to warp. Warpage of the strips may be caused, for example, by the mismatch of coefficients of thermal expansions (CTEs) of the various components of the package strip such as the package substrate and semiconductor dies, or different layers of the package substrate. The amount of warpage is also affected by the size, thickness, and materials of the package substrate, and/or the semiconductor die. This warpage may cause problems later in manufacturing and processing, and cause damage to the semiconductor dice and reduce wafer yield, therefore needs to be reduced.

However, conventional magazines only carry the package strips between processes regardless of the strip warpage improvement.

US patent publication No. U.S. Pat. No. 7,172,927 discloses a carrier assembly including a carrier having angled lands and side-insertion clamp structures. The clamp structures have angled clamp fins used to control cure-induced warpage of package strips during post encapsulant cure (PEC). The angled lands and angled side-insertions clamps are used to clamp the edges of the package strip in order to introduce an intentional deformation which counters warpage that occurs during PEC.

Korean patent publication No. KR10-0716418 discloses a carrier assembly having a body having an inner wall and an outer wall, the inner wall having inwardly protruding guide lands and slot holes between the holding lands. The carrier assembly also includes a movable plate vertically installed between the inner and outer wall, and the movable plate has holding lands used to be inserted into the slot holes for supporting the strips. The carrier assembly is used to clamp the strips between the guide lands and the holding lands after an upward movement of the plate relative to the carrier assembly body. Locking member is provided to hold the plate at the end of the upward movement.

US patent publication No. US20220392795 discloses a semiconductor manufacturing equipment having an outer case housing including a lower case extension fixed in position within the outer case housing to support a semiconductor plate, and an inner case housing having an upper case extension disposed within the outer case housing and in proximity to the lower case extension. The equipment includes a cam assembly disposed above the inner case housing and operatable with a handle to rotate the cam assembly and apply pressure to the inner case housing and upper case extension, so as to lock the semiconductor plate in place between the upper case extension and lower case extension. A spring or other elastic mechanism is disposed under the inner case housing to load the pressure.

There exists a need to further improve and facilitate the conventional magazines.

### SUMMARY OF THE INVENTION

An objective of the present application is to provide a semiconductor carrier assembly for carrying semiconductor package strips, for example for transport and manufacturing processes.

According to an aspect of the present application, a carrier assembly for carrying semiconductor package strips is provided. The carrier assembly comprises a carrier main body comprising a housing, the housing comprising side walls having supporting slots for carrying the semiconductor package strips inside the housing, respectively, and the housing defining a front opening and a rear opening between the side walls to allow for placement and displacement of the semiconductor package strips, and a pair of clamping devices for applying clamping forces to the semiconductor package strips against the supporting slots, respectively, and each of the pair of clamping device comprising a locking plate, strip contacting extensions extending from the locking plate and insertable through one of the front opening and the rear opening of the housing, and a locking member for moving the strip contacting extensions between a locked position and an unlocked position, wherein in the locked position the substrate package strips are pressed against the supporting slots by the respective strip contacting extensions.

By compressing each package strip between strip contacting extensions and the corresponding supporting slots, the invention allows reducing warpage of the strips, especially during packaging process of the strips, for example during PBM.

The carrier main body according to the present invention may be a conventional magazine. In this way, the present invention provides a simple and cost-effective way to improve a conventional magazine so as to securely carry package strips in the magazine and decrease warpage during processing of the strips.

According to another aspect of the present application, it is provided a clamping device for a magazine comprising a housing, the housing comprising side walls having supporting slots for carrying the package strips inside the housing, each strip being carried by a corresponding supporting slots. The clamping device comprises strip contacting extensions configured to be inserted through front or rear openings of the housing and locking member for maintaining the strip contacting extensions in a pre-determined position, the strip contacting extensions being configured to press each strip towards the corresponding supporting slots supporting the said package strip in the pre-determined position.

According to another aspect of the present application, a method for carrying semiconductor package strips with a carrier assembly is provided, wherein the carrier assembly comprises a carrier main body and a pair of clamping devices. The method comprises placing the semiconductor package strips through one of a front opening and a rear opening of a housing of the carrier main body and inside the housing, wherein each of the semiconductor package strips is carried between a pair of supporting slots at a pair of side walls of the housing: attaching the pair of clamping device to the carrier main body at the front opening and the rear opening of the carrier main body respectively, such that strip contacting extensions extending from a locking plate of each clamping device are insertable through one of the front opening and the rear opening of the housing to a distance above the semiconductor package strips, respectively; and moving the strip contacting extensions to a locked position such that clamping forces are applied to the semiconductor package strips against the supporting slots by the strip contacting extensions, respectively.

The present invention allows improved warpage issue by applying a clamping device to an existing magazine and therefore strip warpage issue can be improved at low cost. The method of the invention can be applied before singulation if warpage improvement is needed in strip condition. The invention can reduce the warpage issue during the heating process, i.e., during pre-bake & post curing process, for example, in the case of dual side molding. In case that severe warpage issue occurs after the top molding, the invention allows improvement of the warpage before the bottom molding through a pre-baking step with the magazine.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate, respectively in front and side views, a conventional semiconductor carrier in the form of a magazine.

FIGS. 2A and 2B illustrate, respectively in front and side views, a carrier assembly according to an embodiment of the present invention, before locking of the clamping device.

FIGS. 3A and 3B illustrate, respectively in front and side views, the carrier assembly of FIGS. 2A and 2B, after locking of the clamping device.

FIGS. 4A and 4B illustrate, in front and side views, an embodiment of the clamping device, before and after locking of the clamping device. FIG. 4C illustrates the locking process.

FIG. 5 illustrates, in side view, a variant of an embodiment of the clamping device.

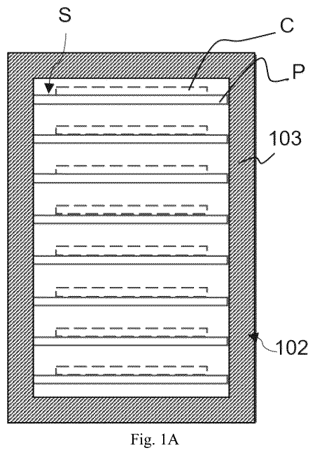

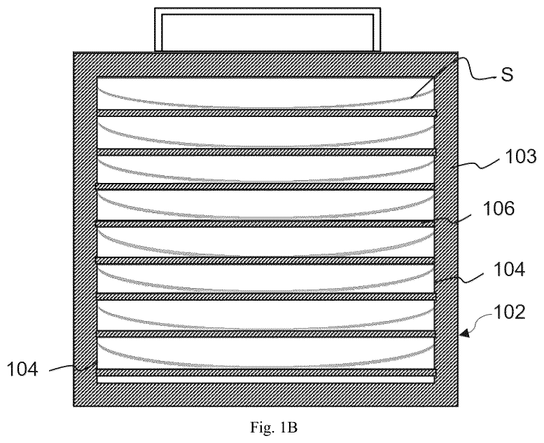

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, warpage of the package strip may occur during manufacturing, in particular during process involving application of heat. The warpage may cause damage to the semiconductor die and reduce wafer yield, therefore needs to be minimized. Also, if strip warpage is improved, for example when strip warpage is less than 3.0 mm, automation is possible during mold process, which will reduce the cost of the manufacturing process. In order to address these issues, the present application provides a clamping device for clamping the package strips inside a magazine in a locked position of the clamping device.

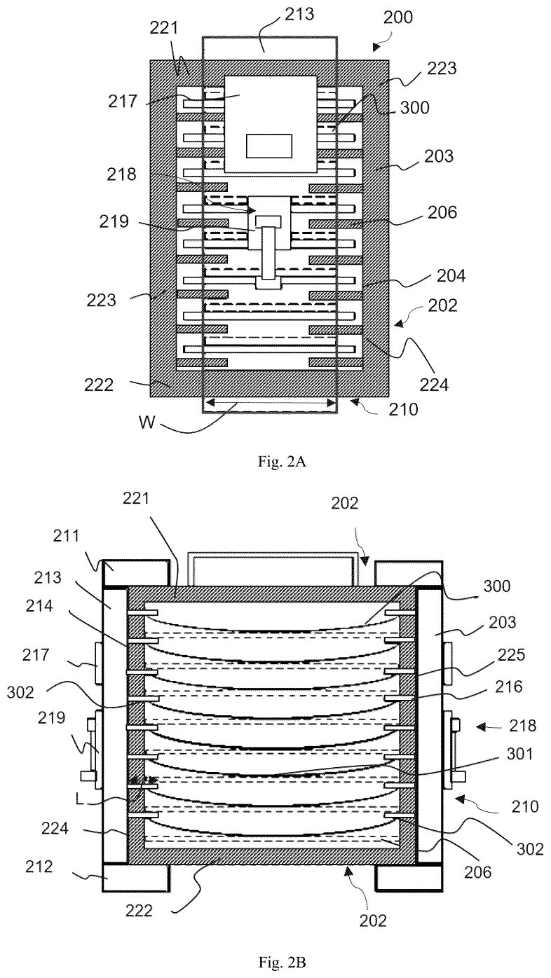

FIGS. 2A and 2B illustrate front and side views of a carrier assembly 200 including a carrier main body 202 and a clamping device 210 according to an embodiment of the present invention, before locking of the clamping device 210. The carrier main body 202 may be a conventional magazine which may need further tools for improving the security and control warpage of the packaging strip carried therein.

As shown in FIGS. 2A and 2B, the carrier main body 202 includes a housing 203 having a top wall 221, a bottom wall 222 and side walls 223 that connect the top wall 221 with the bottom wall 222. The side walls 223 may include on their internal surfaces 204, supporting slots 206 for carrying the package strips 300. Each strip 300 rests on a corresponding supporting slot 206. The supporting slots 206 are for example in the form of ribs or grooves that extend horizontally along the internal surfaces 204 of the side walls 223. The supporting slots 206 are preferably situated at regular intervals between the top and bottom walls 221, 222 of the housing 203. The housing 203 further includes, respectively on its front and rear end and between the side walls 222 and 223, front and rear openings 224 and 225. The package strips S may be introduced into the housing 203 from the front opening 224 or the rear opening 225. The housing 203 is preferably substantially parallelepiped. The front and rear openings preferably have the same dimensions.

In the illustrated embodiment as shown in FIG. 2B, the strips 300, once warped, rest in the supporting slots by a central zone 301 of the strips S. Two edges 302 of the strips S situated near the front and rear ends of the housing 203 are deviated compared to the central zone 301 of the strip 300. More particularly, with regard to the supporting slots 206 in which the strips 300 rest, the edges 302 of a strip 300 situated near the front or rear end of the housing 203, i.e., the front or rear edge 302 of the strip 300, may become more elevated compared to the central zone 301 of the strip 300. During packaging, for example in the pre-baking before mold process or post curing, the deviation of the edges 302 may become larger if no measure for controlling the strip warpage is taken.

In the present invention, a pair of clamping devices 210 are arranged respectively at the front and rear ends of the housing 203. The two clamping devices 210 are preferably identical to each other. Each clamping device 210 includes a locking plate 213 that is suitable to be placed against the front opening 224 or the rear opening 225 of the housing 203. As illustrated, the locking plate 213 includes, on an inwardly oriented surface 214 facing the carrier main body 202, strip contacting extensions 216 in the form of fins protruding preferably perpendicularly from the locking plate 213. The strip contacting extensions 216 preferably extend parallel to each other. Each strip contacting extension 216 is insertable at a distance above the corresponding supporting slot 206 to contact a front or a rear edge 302 of a semiconductor package strip 300 carried by the corresponding supporting slot 206. In particular, each strip contacting extension 216 is inserted above a front or a rear edge 302 of a strip 300. Each strip contacting extension 216 is preferably inserted in proximity and at a distance above the front or rear edge 302 of the strip 300, the distance for example depends on the degree of warpage of the strip before the insertion of the strip contacting extension 216. In one embodiment, the strip contacting extensions 216 may have rounded ends. Preferably: the strip contacting extensions 216 extend along the entire width W of the locking plate 213. The strip contacting extensions 216 are preferably arranged equidistantly on the inwardly oriented surface 214 of the clamping device 210. For example, the distance between adjacent strip contacting extensions 216 is equal to the distance between adjacent supporting slots 206 of the housing 203.

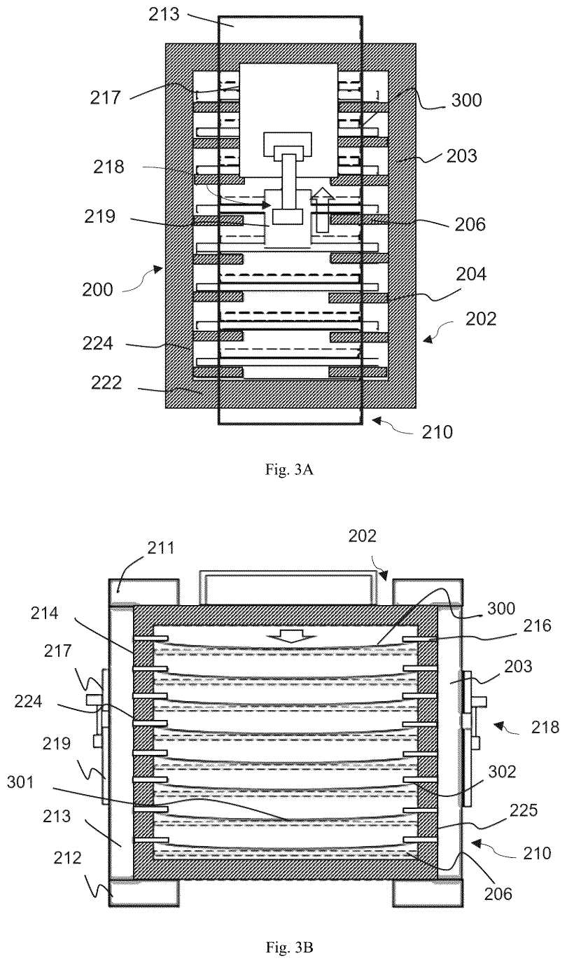

The locking plate 213 is configured to be vertically movable relative to the assembly main body 202 after insertion of the strip contacting extensions 216 and before locking of the strip contacting extensions 216. The movement of the locking plate 213 thus allows vertical movement of the strip contacting extensions 216 relative to the housing 203. As can be seen in FIG. 3B, a downward movement of the strip contacting extensions 216 relative to the housing 203 results in that the strip contacting extensions 216 press against the front and rear edges 302 of the strips 300. The forces exerted by the strip contacting extensions 216 on the front and rear edges 302 of the strips 300 tend to compress the strips 300 and thus counter the deviation of the edges 302 of the strips 300 relative to the central zone 301 of the strips 300 and thereby control or reduce warpage of the strips 300.

Once the desired movement of the strip contacting extensions 216 is reached, the strip contacting extensions 216 are maintained in a locked position via a locking member 218 of the clamping device 210. The locking member 218 may include a first locking element 217 and a second locking element 219 which can be engaged with each other or further disengaged from each other. The first locking element 217 is for example fixed to the locking plate 213 and can move with the locking plate 213. The locking element 219 is for example fixed to the other portion of the clamping device that cannot vertically move relative to the assembly main body 202 after insertion of the strip contacting extensions 216. The first and second locking elements 217 and 219 may engage with each other to lock the locking plate 213 in a pre-determined locked position relative to the housing 203. In one embodiment, the locking plate 213 may be locked via the locking member 218 in several different pre-determined locked positions, therefore allowing different degree of control of the warpage of the strips 300. For example, the vertical position of the second locking element 219 may be adjusted so as to allow the first locking element 217 to engage with the second locking element 219 on different heights of the housing 203, therefore locking the locking plate 213 and the strip contacting extensions 216 thereon in different positions. In one embodiment, the locking plate 213 may include a biasing element, for example in the form of a spring. The biasing force of the biasing element may be adjusted to move the strip contacting extensions 216 to respective locked positions. The movement of the locking plate 213 may thus be controlled by the biasing element. For example, the locking plate 213 is configured to remain at a topmost position when it is not locked so as to facilitate the insertion of the strip contacting extension in the unlocked position of the clamping device. In some embodiments, force detection means may be deployed on the locking member 218 to detect, for example, the rebound forces from the strips to avoid significant forces or pressures applied to the strips that may cause damages thereto.

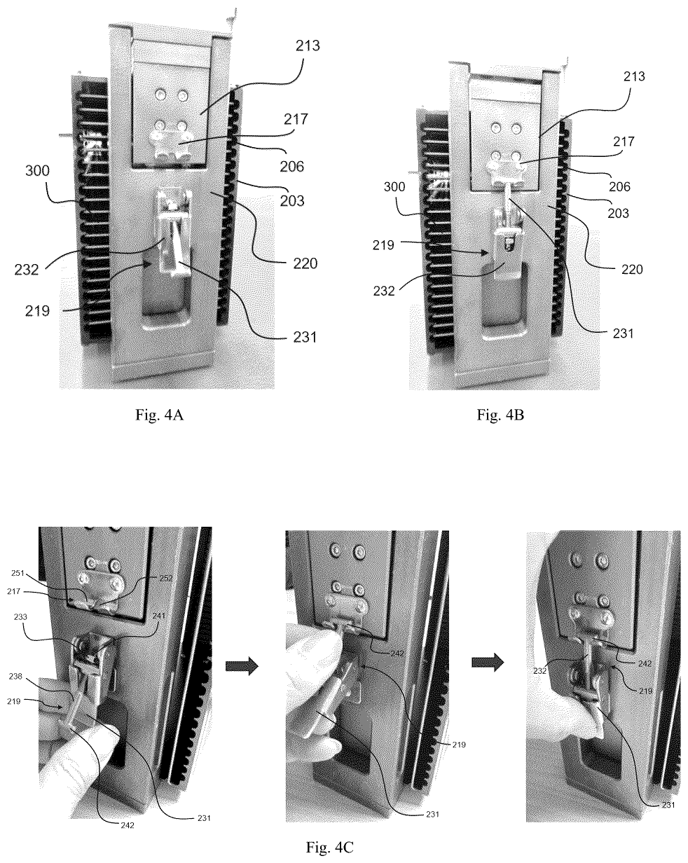

FIG. 4A and FIG. 4B illustrate 219 an example of the locking member 218 in the unlocked position and the locked position, respectively. FIG. 4C illustrates the locking process with an enlarged view of the first and second locking elements 217 and 219. As shown, the second locking element 219 includes a rotatable plate 231 that is rotatable in a horizontal direction about a hinge or another similar structure and a rod 232 that is inserted through an opening in the rotatable plate 213. The rod 232 includes a rod body 238 and translation of the rod body 238 within the opening may be blocked at a first end 241 of the rod 232 by a blocking element 233 of the rod, for example in the form of a screw fixed near the first end 241. A second end 242 of the rod 232 may comprise projections extending perpendicularly to the longitudinal direction of the rod 232. The first locking element 217 includes a corresponding groove 251 or slot for receiving the second end 242 of the rod 232 when it is in the locked position. The groove 251 includes an aperture 252 for allowing passage of the rod 232. In order to lock the locking member 218, the second locking element 219 is rotated upwards to allow engagement of the second end 242 of the rod 232 in the groove 251. Then the rotatable plate 231 is rotated downward to block upward movement of the second end 242 of the rod 232.

The clamping device 210 may further include a supporting element, for example in the form of a stand 220, which cannot move vertically relative to the assembly main body 202 after insertion of the strip contacting extensions 216. The locking plate 213 can for example move translationally relative to the stand 220. For example, the locking plate 213 may move vertically relative to the stand 220, with the strip contacting extensions 216 moving vertically as well. The second locking element 219 may be fixed to the stand 220. The locking plate 213 is at least partially received in the stand 220 while the locking plate 213 is able to move vertically inside of the stand 220.

The clamping device 210 may further include upper and lower securing elements 211 and 212 for positioning and optionally fixing the clamping device 210 to the housing 203. Preferably, the distance between the upper and lower securing elements 211 and 212 is adjustable so that the user may adjust the distance according to the height of the carrier main body 202. In one embodiment, the upper securing elements 211 is integrally formed with the stand 220 of the clamping device 210. Each clamping device 210 may include two upper 211 and two lower 212 securing elements.

In one embodiment, the clamping devices 210 may be added successively to the carrier main body 202. In one embodiment, the stand 220 and the locking plate 213 are horizontally movable relative to the lower securing element 212. To place the clamping devices 210 on the carrier main body 202, the carrier main body 202 may be first placed on the lower securing elements 212. Then the stand 220 and the locking plate 213 are pushed horizontally towards the carrier main body 202, for example via a translational movement, to insert the strip contacting extensions 216 through the front and rear opening 224, 225 of the housing 203 above the strips 300. The alignment between the clamping device 210 and the carrier main body 202 can be ensured through the horizontal movement of the stand 220, with the vertical movement of the stand 220 restricted or prohibited. The clamping device 210 may be configured in a way that when the strip contacting extensions 216 are fully inserted into the housing 203, the clamping device 210, for example the locking plate 213 or the stand 220, abuts the front and rear opening 224, 225 of the housing 203.

The clamping device 210 may be fixed to the carrier main body 202, for example by screwing. For example, the upper securing elements 211 and the housing 203 may include screw holes allowing the clamping devices 210 to be connected to the housing 203 by screwing. Other fixing means for connecting the clamping devices 210 to the carrier main body 202 do not extend beyond the scope of the present invention.

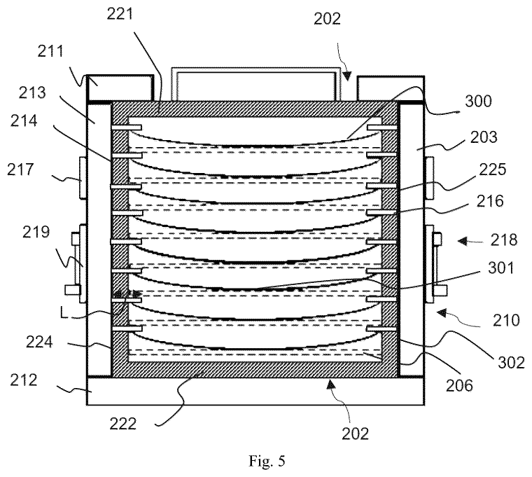

In one embodiment, the lower securing elements 212 of the clamping devices 210 are connected before the carrier main body 202 is placed on the lower securing elements 212, so as to facilitate the positioning of clamping device 210 on the carrier main body 202. In one embodiment as illustrated in FIG. 5, the lower securing elements 212 of the clamping devices 210 placed in the front and rear of the carrier main body 202 are integral. In this case, the clamping device of the embodiments of the invention includes a front and a rear clamping part, each clamping part may correspond to a clamping device 210 as previously described.

### Examples

Clamping devices according to the present invention are added to the front and rear end of a conventional magazine during pre-baking before mold process (PBM). The warpage of the strips is compared with that obtained with the same magazine without clamping devices.

As can be seen from the table I below, the invention showed better effectiveness in strip warpage controlling than conventional magazine and strip warpage is improved.

Further, with the invention, strip warpage is less than 3.0 mm. In this case, the molding of the encapsulant can be automated, which further improve the efficiency and cost of the manufacturing process of the strips.

TABLE I

| | |
|---|---|
| Bare printed circuit | After pre-baking |
| board (PCB) | before mold process |

| Warpage | Type of magazine | Warpage |
|---|---|---|
| +0.7 mm | Conventional | +3.7 mm |
| +0.6 mm | Conventional | +3.7 mm |
| +1.1 mm | Invention | +2.8 mm |
| +0.6 mm | Invention | +2.7 mm |

The discussion herein included numerous illustrative figures that showed various portions of a carrier assembly for carrying semiconductor package strips. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A carrier assembly for carrying semiconductor package strips, comprising:
a carrier main body comprising a housing, the housing comprising side walls having supporting slots for carrying the semiconductor package strips inside the housing, respectively, and the housing defining a front opening and a rear opening between the side walls to allow for placement and displacement of the semiconductor package strips, and
a pair of clamping devices for applying clamping forces to the semiconductor package strips against the supporting slots, respectively, and each of the pair of clamping device comprising:
a locking plate,
strip contacting extensions extending from the locking plate and insertable through one of the front opening and the rear opening of the housing, and
a locking member for moving the strip contacting extensions between a locked position and an unlocked position, wherein in the locked position the semiconductor package strips are pressed against the supporting slots by the respective strip contacting extensions.

2. The carrier assembly of claim 1, wherein the pair of clamping devices are arranged respectively at the front opening and the rear opening of the housing of the carrier main body.

3. The carrier assembly of claim 1, wherein each strip contacting extension is insertable at a distance above the corresponding supporting slot to contact a front edge or a rear edge of a semiconductor package strip carried by the corresponding supporting slot.

4. The carrier assembly of claim 1, wherein the locking member comprises first and second locking elements configured to keep the strip contacting extensions in the locked position when the first and second locking elements are engaged.

5. The carrier assembly of claim 4, wherein the locking plate is vertically movable relative to the housing after insertion of the strip contacting extensions and before locking of the strip contacting extensions.

6. The carrier assembly of claim 5, wherein the first locking element is fixed to the locking plate.

7. The carrier assembly of claim 5, wherein the clamping device comprises a stand, the locking plate being vertically movable relative to the stand.

8. The carrier assembly of claim 7, wherein the second locking element is fixed to the stand.

9. The carrier assembly of claim 1, wherein the clamping device and the housing comprises screw holes allowing the pair of clamping devices to be fixed to the housing.

10. The carrier assembly of claim 1, wherein the strip contacting extensions are in the form of fins protruding perpendicularly from the stand and in parallel with each other.

11. A clamping device for applying clamping forces to the semiconductor package strips in a magazine comprising a housing, the housing comprising side walls having supporting slots for carrying the semiconductor package strips inside the housing, respectively, and the housing defining a front opening and a rear opening between the side walls to allow for placement and displacement of the semiconductor package strips, the clamping device comprising a locking plate, strip contacting extensions extending from the locking plate and insertable through one of the front opening and the rear opening of the housing and locking member for moving the strip contacting extensions between a locked position and an unlocked position, wherein in the locked position the substrate package strips are pressed against the supporting slots by the respective strip contacting extensions.

12. The clamping device of claim 11, wherein the vertical position of the second locking element is adjustable so as to allow the first locking element to engage with the second locking element on different heights of the housing.

13. A method for carrying semiconductor package strips with a carrier assembly, wherein the carrier assembly comprises a carrier main body and a pair of clamping devices, and the method comprises:
placing the semiconductor package strips through one of a front opening and a rear opening of a housing of the carrier main body and inside the housing, wherein each of the semiconductor package strips is carried between a pair of supporting slots at a pair of side walls of the housing;
attaching the pair of clamping device to the carrier main body at the front opening and the rear opening of the carrier main body respectively, such that strip contacting extensions extending from a stand of each clamping device are insertable through one of the front opening and the rear opening of the housing to a distance above the semiconductor package strips, respectively; and
moving the strip contacting extensions to a locked position such that clamping forces are applied to the semiconductor package strips against the supporting slots by the strip contacting extensions, respectively.

14. The method of claim 13, further comprising:
applying a predetermined process the semiconductor package strips when the strip contacting extensions are in the locked position.

15. The method of claim 14, wherein the predetermined process is a pre-baking before molding process.

16. The method of claim 13, further comprising fixing the clamping device to the housing by screwing.
